(19) United States
(12) Patent Application Publication
(10) Pub. No.: US 2007/0108501 A1
(43) Pub. Date: May 17, 2007

(54) SRAM circuit having a SONOS-based NAND device

(75) Inventor: Diana Ding Yuan, Boise, ID (US)

Correspondence Address: PERKINS COIE LLP, P.O. BOX 2168, MENLO PARK, CA, 94026, US

(73) Assignee: Nantronics Semiconductor, Inc.

(21) Appl. No.: 11/595,724

(22) Filed: Nov. 9, 2006

Related U.S. Application Data
(62) Division of application No. 11/251,068, filed on Oct. 14, 2005.
(60) Provisional application No. 60/718,089, filed on Sep. 16, 2005.

(51) Int. Cl. H01L 29/788; H01L 21/8238

(52) U.S. Cl. 257/315; 438/211; 257/E29.129

(57) ABSTRACT

The present invention discloses a resonant tunneling device. Further, the present invention discloses a memory storage device utilizing a resonant tunneling barrier. Moreover, the present invention teaches an SRAM circuit utilizing a resonant tunneling device. Additionally, the present invention teaches an NROM and NAND device utilizing a resonant tunneling barrier.

### CROSS REFERENCE TO RELATED APPLICATIONS

This application is a divisional of U.S. Utility patent application Ser. No. 11/251,068, filed Oct. 14, 2005, which in turns claims the benefit of U.S. Provisional Patent Application No. 60/718,089 filed Sep. 16, 2005, both of which are hereby incorporated by reference in their entirety.

### BACKGROUND

Quantum mechanics provides that the instantaneous state of a quantum system is depicted by the probabilities of its measurable properties. The measurable properties at a quantum level typically include energy, position, momentum, and angular momentum. Because the instantaneous state is depicted by probabilities, the measurable properties are not assigned a definite value. Rather, quantum mechanics predicts these values using probability distributions. The probability distributions provide the probability of obtaining possible outcomes based upon an instant measurement. However, certain states exist that are associated with a definite value of a particular measurable property. These definite values are commonly known as “eigenstates.”

Quantum tunneling is the quantum-mechanical process in which an electron, with less energy, passes through an electric field, with more energy. As the electron approaches an electric field with more energy, classically, the electron would be repelled. Under quantum mechanics, once the electron reaches the electric field, a finite probability exists that the electron will be located on the other side of the electric field. Based upon this probability, the electron will tunnel through the electric field to the other side of the electric field even though the electron's energy level is lower.

These unique characteristics of tunneling are useful in modern electronics. For example, a resonant tunneling diode (hereinafter “RTD”) has been developed by Texas Instruments. The RTD's tunneling characteristics allow operation in several electrical states. Thus, several logical states can be represented by a single component. However, to date, all previous tunneling related research has been focused on III-V semiconductor compounds.

Prior Art FIG. 1 illustrates a floating gate transistor 100 which is another device that utilizes tunneling. The floating gate transistor 100 is comprised of a source 101 and a drain 102. In between the source 101 and the drain 102 are four distinct layers. A gate electrode 103 is a top layer. A blocking layer 104 is a second layer. A floating gate 105 is a third layer. A tunneling oxide 106 is a fourth layer.

Typically, the floating gate transistor 100 is programmed by flowing electrons from the source 101 to the drain 102. To facilitate programming, a large voltage introduced on the gate electrode 103 that causes electrons to flow into the floating gate 105. To erase, a large voltage differential is place between the control gate 103 and the source 101. The electrons are removed through quantum tunneling.

As shown, the floating gate transistor 100 requires a high operational voltage. This high voltage is problematic as it poses a threat to the integrity of the tunneling oxide and can cause damage to the tunneling material. Further, the tunneling oxide is prone to accidental tunneling which causes the device to be unreliable.

Prior Art FIG. 2 represents another device that utilizes tunneling, namely a NROM device 150. A NROM cell is an n-channel MOSFET device where a gate dielectric is replaced with a trapping material. Programming is performed by channel hot idle injection. Erasing is performed by tunneling enhanced hot idle injection. As shown, a NROM 150 consists of an oxide layer 156 coupled to a source 152 and a drain 153. A Si₃N₄ layer 155, a trapping layer, is sandwiched between an oxide layer 156 and a SiO₂ layer 154, a top layer. The oxide layer is a tunneling layer and is typically SiO₂. The NROM as shown requires high voltage to program and erase bits from storage. Thus, the NROM is problematic as it is susceptible to severe short channel effects.

Prior Art FIG. 3 represents a SONOS-based NAND device. As shown, a SONOS-based NAND stack 200 consists of a Si₃N₄ layer 201 sandwiched between a Al₂O₃ layer 202 and a SiO₂ layer 203. The Si₃N₄ layer 201 is a trapping layer while the SiO₂ layer 203 is a tunneling layer. As shown, the SONOS-based NAND stack 200 shares the same problems as the NROM device having a high operating voltage and being susceptible to short-channel effect.

A further example where tunneling has been extended is static random access memory devices (hereinafter “SRAM”). Typically, each bit in a SRAM system is stored on four transistors. These transistors form two cross-coupled inverters having two stable states. The two stable states represent 0 and 1. Although this method is effective in storing bits, utilizing a multitude of transistors is costly in terms of space, power, speed and price.

A multivalued SRAM cell using a vertically integrated multipeak RTD has been used in lieu of typical SRAM devices. Implementing the multipeak RTD has reduced size and power dissipation while increasing speed. However, the process is expensive and the multivalued SRAM cell is not silicon-based CMOS compatible.

What is needed is a device that utilizes alternate compounds to create resonant tunneling devices. Further, what is needed is a device that performs the same function as a tunneling oxide without the high voltage and unreliability. Moreover, what is needed is a NMOS device that operates at low voltages and does not have a severe short channel effect. Additionally, what is needed is SRAM circuitry which utilizes a silicon-based CMOS compatible process.

### SUMMARY OF INVENTION

The present invention teaches a resonant tunneling device comprising alternate compounds. Further, the present invention teaches a storage device, a NROM, and a SONOS-based NAND. Moreover, the present invention teaches a SRAM circuit that can be fabricated using a silicon-based CMOS compatible process.

In one embodiment, a resonant tunneling device comprises a first bandgap, a second bandgap, and a third bandgap. The third bandgap is sandwiched between the first bandgap and the second bandgap. The first bandgap and the second bandgap are larger than the third bandgap thus facilitating resonant tunneling.

In additional embodiments, the first and/or second bandgap can be SiO₂ or Al₃O₄. The third bandgap, in additional embodiments, can be poly-crystalline silicon, crystalline silicon, Pt, Ir, Ni, Ge, Be, Re, TaO, TaN, BaTiO, BaZrO, ZrO, HfO, TiN, Ti, ZrN, WN, Mo, MoN, or MoSi. In further embodiments, the first, second, and third bandgap can be a variety of material suitable for facilitating resonant tunneling.

In another embodiment of the present invention, a storage device is disclosed. The storage device comprises a source, a resonant tunneling barrier, a drain, a floating gate, a blocking layer, and a gate electrode. The resonant tunneling barrier is coupled to the source and the drain. The floating gate is sandwiched between the resonant tunneling barrier and the blocking layer. The blocking layer is sandwiched between the floating gate and the gate electrode. In additional embodiments, the resonant tunneling barrier can be the same as the embodiments disclosed above, or can be any other device suitable for facilitating resonant tunneling. In further embodiments, the blocking layer can be a thin-oxide film. Moreover, in other embodiments, the device can be used to facilitate flash memory, NAND, NOR, NROM, and/or MirrorBit.

In an alternate embodiment, the present invention discloses a SRAM circuit. The SRAM circuit comprises a transistor having a source, a gate, and a drain. The SRAM circuit further comprises a bitline coupled to the source of the transistor and a wordline coupled to the gate of the transistor. A resonant tunneling device is coupled to the drain and a load. In additional embodiments, the resonant tunneling device can be similar to the embodiments disclosed above or can be any other device suitable for facilitating resonant tunneling. Further, the load can vary depending on the intended and/or desired use of the circuit and can include, but is not limited to, a resistive load, current source, and resonant tunneling load.

In a further embodiment, a NROM storage device is disclosed. In a certain embodiment, the NROM device comprises a top layer, a resonant tunneling barrier layer, a small bandgap trapping layer, a source and a drain. The resonant tunneling barrier layer is coupled to the source and the drain. Further, the small bandgap trapping layer is sandwiched between the top layer and the resonant tunneling barrier layer. In alternate embodiments, the small bandgap trapping material can be TaO or BTiO. However, in further embodiments, the small bandgap trapping layer can be any material suitable for facilitating resonant tunneling. Moreover, in certain embodiments the top layer can be SiO₂. In other embodiments, the resonant tunneling barrier layer can be similar to the embodiments disclosed above or can be any other device suitable for facilitating resonant tunneling.

In an additional embodiment, the present invention discloses a SONOS-based NAND stack. The SONOS-based NAND stack comprises a top layer, a resonant tunneling barrier layer, and a small bandgap trapping layer. The small bandgap trapping layer is sandwiched between the top layer and the resonant tunneling barrier layer. In other embodiments the small bandgap trapping layer can be TaO or BTiO and the top layer can be SiO₂. However, in further embodiments, the small bandgap trapping layer can be any material suitable for facilitating resonant tunneling. The resonant tunneling barrier layer in additional embodiments can be similar to the embodiments disclosed above or can be any other device suitable for facilitating resonant tunneling. In yet another embodiment the SONOS-based NAND device can be integrated on a circuit with the SRAM circuit as disclosed above.

As described above, and in alternate embodiments that would be apparent to one skilled in the art, the implementation of resonant tunneling with a variety of materials, in a variety of devices, can solve the problems raised in the prior art.

### BRIEF DESCRIPTION OF DRAWINGS

FIG. 1 illustrates a floating gate transistor in the prior art.

FIG. 2 illustrates a NROM in the prior art.

FIG. 3 illustrates a SONOS-based NAND stack in the prior art.

FIG. 4 illustrates a floating gate transistor with a resonant tunneling barrier.

FIG. 5 illustrates a resonant tunneling barrier.

FIG. 5A illustrates another embodiment of a resonant tunneling barrier.

FIG. 6 illustrates a graph comparing a resonant tunneling barrier to a single layer oxide.

FIG. 7 illustrates a semiconductor band diagram of a resonant tunneling barrier.

FIG. 8 illustrates a NROM with small bandgap trapping material and a resonant tunneling barrier.

FIG. 9 illustrates a SONOS-based NAND stack.

FIG. 10 illustrates a SRAM circuit with a resistive load and resonant tunneling device.

FIG. 11 illustrates a graph of the SRAM circuit illustrated in FIG. 10.

FIG. 12 illustrates a SRAM circuit with a current source load and a resonant tunneling device.

FIG. 13 illustrates a graph of the SRAM circuit illustrated in FIG. 12.

FIG. 14 illustrates a SRAM circuit with a resonant tunneling load and a resonant tunneling device.

FIG. 15 illustrates a graph of the SRAM circuit illustrated in FIG. 14.

FIG. 16 illustrates a graph of an SRAM circuit having two bits per cell.

FIG. 17 illustrates a voltage scaling graph.

FIG. 18 illustrates a SRAM circuit with no load.

FIG. 19 illustrates a SRAM circuit with a capacitor.

FIG. 20 illustrates a block diagram of an integrated circuit.

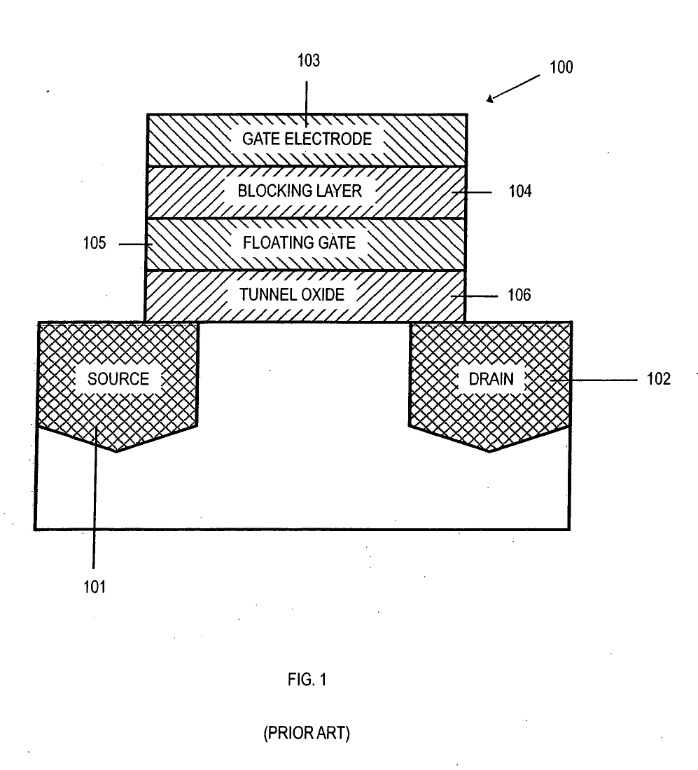

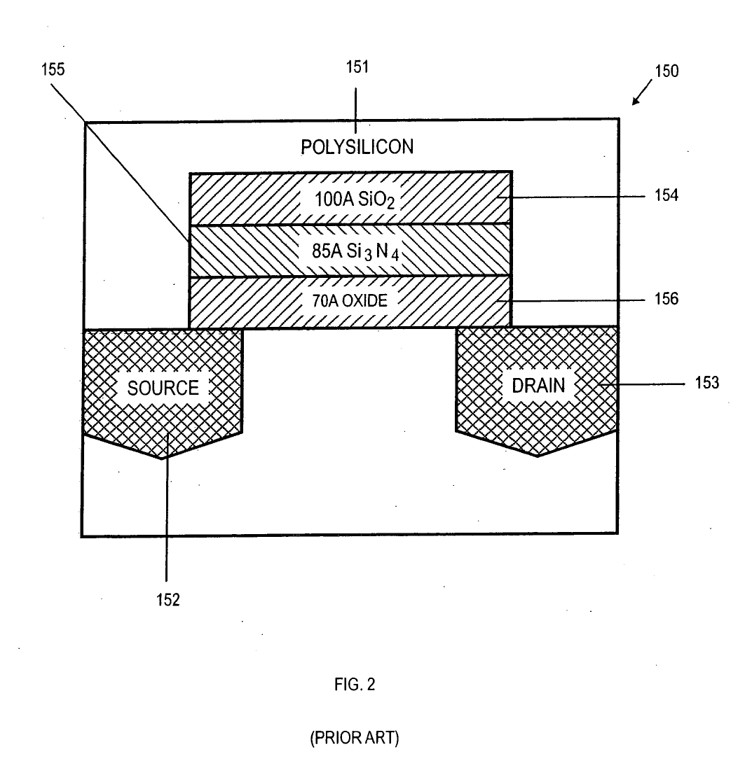

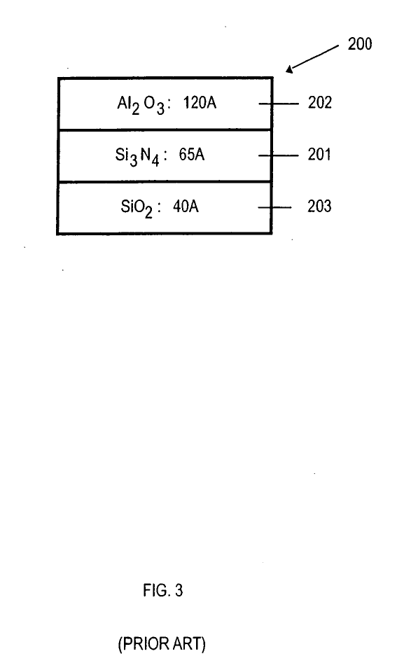

### DETAILED DESCRIPTION OF DRAWINGS

The present invention teaches a variety of devices, methods, and other subject matter described herein or apparent to one skilled in the art in light of the present teaching. The present invention further teaches a variety of embodiments, aspects and the like, all distinctive in their own right. The person of skill in the art suitable for the present invention can have a background from electrical engineering, computer science, computer engineering, or the like.

The present invention teaches alternate compounds which can be used to fabricate resonant tunneling devices. In addition, the present invention teaches to replace a tunneling oxide, which is commonly used in flash memory devices, with a resonant tunneling barrier. Moreover, the present invention teaches the use of a resonant tunneling barrier with NROM and SONOS-based NAND devices. Further, the present invention teaches the fabrication of an SRAM device using a silicon-based CMOS compatible process.

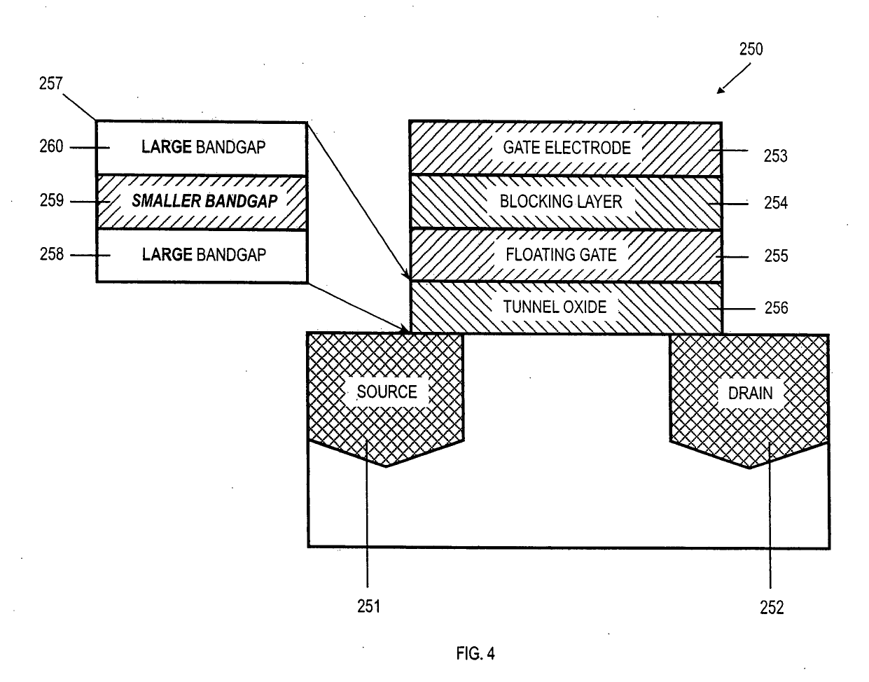

FIG. 4 illustrates a floating gate transistor 250 with a resonant tunneling barrier. In the embodiment illustrated in FIG. 4, a floating gate transistor 250 comprises a source 251, a drain 252, a gate electrode 253, a blocking layer 254, a floating gate 255, and a resonant tunneling barrier 257. In the embodiment illustrated, the resonant tunneling barrier 257 comprises a small bandgap 259 sandwiched between two large bandgaps 258 and 260. The resonant tunneling barrier 257 is coupled to the source 251 and the drain 252. The floating gate 255 is sandwiched between the blocking layer 254 and the resonant tunneling layer 257. The gate electrode 253 is on top of the blocking layer 254.

Comparing the embodiment illustrated in FIG. 4 to a typical flash memory cell, the on-chip voltage, by way of example and not limitation, can be reduced from approximately 20-25V to approximately 8V. However, in alternate embodiments these approximations can vary greatly depending on fabrication techniques, availability of known and/or convenient compounds, the availability of conducting and/or semi-conducting material, the intended and/or desired use of the circuit, etc. In addition, the benefits of the resonant tunneling barrier include, but are not limited to, increased reliability, little or no high voltage threat to oxide integrity, little or no damage to tunneling material, little or no need for high voltage circuitry, simplified routing and design, and reduced die size.

In alternate embodiments, a thin oxide film can be used as the blocking layer 254. In further embodiments, the thin oxide layer can replace an oxide-nitride-oxide film which is commonly found in flash memory devices. The benefits of this embodiment include, but are not limited to, facilitated scaling, better gate to substrate control, and less thermal cycle to enable embedded-flash technology.

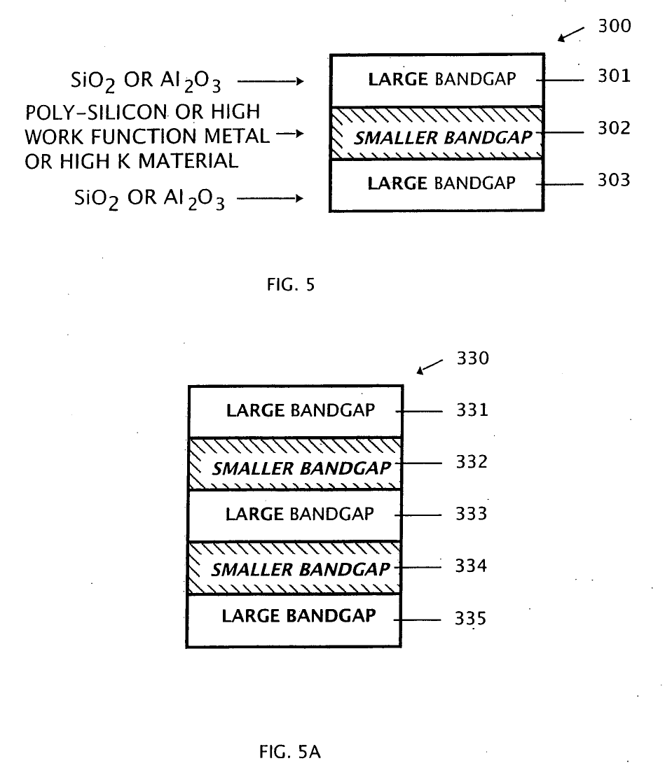

FIG. 5 illustrates a resonant tunneling barrier 300. The resonant tunneling barrier 300 comprises a large bandgap 301, a smaller bandgap 302, and another large bandgap 303. The smaller bandgap 302 is sandwiched between the two large bandgaps 303. As illustrated in the embodiment shown in FIG. 5, the large bandgaps 301, 303 can be SiO₂ or Al₂O₃. In alternate embodiments, the large bandgaps can be any material compatible with current or future silicon CMOS technology. Further, as illustrated, the smaller bandgap 302 can be poly-silicon, high work function metal, high K material, or any other material compatible with current or future silicon CMOS technology. Examples of high work function metals include, but are not limited to, Pt, Ir, Ni, TaN, Ge, Be, and Re. Examples of high K material include, but are not limited to, TaO, TaN, BaTiO, BaZrO, ZrO, and HfO. The list of materials are provided for example only and are no way intended to be an exhaustive list of allowable material.

FIG. 5A illustrates a resonant tunneling barrier 330 having five layers. The resonant tunneling barrier 330 comprises a first large bandgap 331, a first small bandgap 332, a second large bandgap 333, a second small bandgap 334 and a third large bandgap 335. The first small bandgap 332 is sandwiched between the first large bandgaps 331 and the second large bandgap 333. The second small bandgap 334 is sandwiched between the second large bandgap 333 and the third large bandgap 335. As illustrated in the embodiment shown in FIG. 5, the large bandgaps 331, 333 and 335 can be SiO₂ or Al₂O₃. In alternate embodiments, the large bandgaps can be any material compatible with current or future silicon CMOS technology. Further, as illustrated, the small bandgaps 332 and 334 can be poly-silicon, high work function metal, high K material, or any other material compatible with current or future silicon CMOS technology. Examples of high work function metals include, but are not limited to, Pt, Ir, Ni, TaN, Ge, Be, and Re. Examples of high K material include, but are not limited to, TaO, TaN, BaTiO, BaZrO, ZrO, and HfO. The list of materials are provided for example only and are in no way intended to be an exhaustive list of allowable material.

As shown in the embodiment illustrated in FIGS. 5 and 5A, the resonant tunneling barrier comprises three and five layers respectively. However, in alternate embodiments, the resonant tunneling barrier can be any number of oddly stacked layers. For example, an alternate resonant tunneling barrier can comprise five large bandgaps and three small bandgaps.

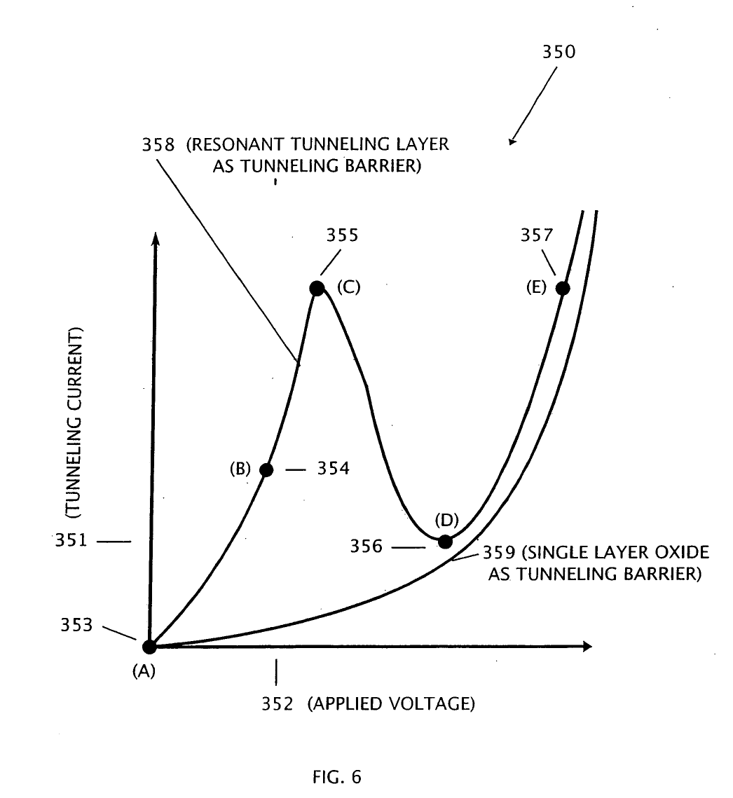

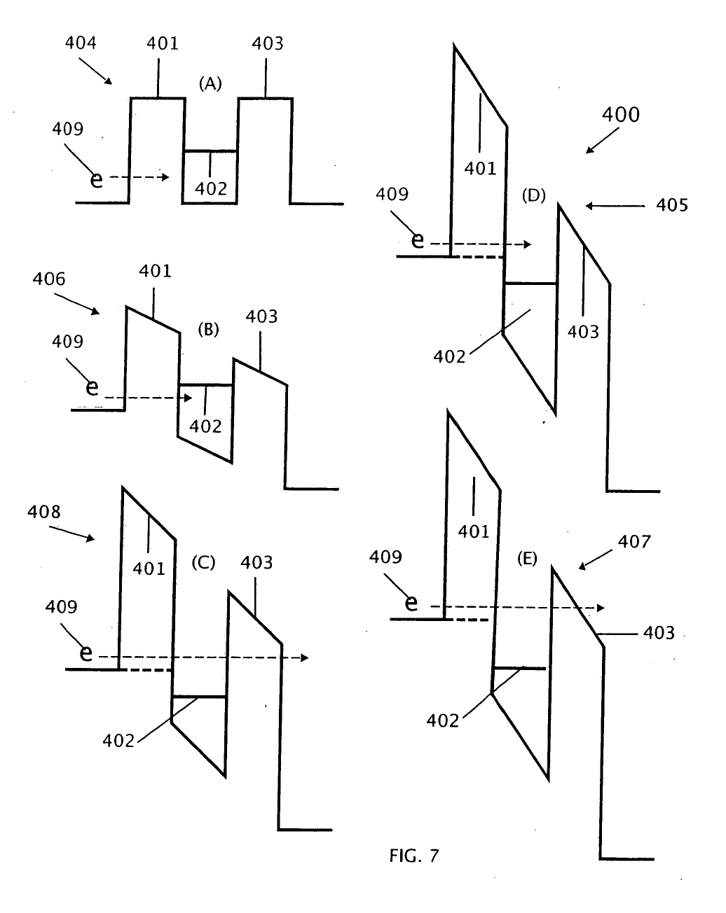

FIG. 6 illustrates a graph 350 comparing a current-voltage plot of a resonant tunneling layer 358 and a single oxide layer 359. The tunneling characteristics (a current-voltage relation) is illustrated in the embodiment shown in FIG. 6 with a tunneling current 351 on a y-axis and an applied voltage 352 on an x-axis. As illustrated, the resonant tunneling barrier current 358 rises sharply as a voltage is increased, as denoted by points A 353, B 354, and C 355. The resonant tunneling barrier current then drops as the voltage is increased past point C 355 as denoted by point D 356. The tunneling current rises again from point D 356 as the voltage is increased, as denoted by point E 357. Points A, B, C, D, and E correspond to the same points denoted in the embodiment illustrated in FIG. 7.

As illustrated in FIG. 6, the single layer oxide 359 gradually increases as the applied voltage 352 is increased. Compared to the resonant tunneling barrier, the single layer oxide requires substantially more voltage to generate the equivalent amount of tunneling current. This is primarily due to the local maxima at point C 355 which corresponds to the eigen-energy level in the center quantum well as illustrated in FIG. 7.

FIG. 7 illustrates a semiconductor band diagram 400 of a resonant tunneling barrier at different applied voltages. As illustrated, each band diagram 404, 405, 406, 407, 408 has two large outside bandgaps 401 and 403 with a small middle bandgap 402. The band diagram corresponding to point A 404 shows no tunneling by an electron 409 at a low voltage 404. However, as the voltage is increased, as denoted by the band diagram corresponding to point B 406, a tunneling current also increases. As the voltage is increased further, as denoted by the band diagram corresponding to point C 408, the electron 409 tunnels through the bandgap and the tunneling current reaches a local maximum at a relatively low voltage. After further increasing the voltage, as denoted by the band diagram corresponding to point D 405, the tunneling decreases thereby decreasing the tunneling current. As the voltage is increased further, as denoted by the band diagram correspond to point E 407, the electron tunnels once again thereby increasing the tunneling current. As shown in the embodiments illustrated in FIGS. 6 and 7, the tunneling current reaches a local maximum at a relatively low voltage thereby eliminating the need for high voltage circuitry and further reducing on-chip voltage operation.

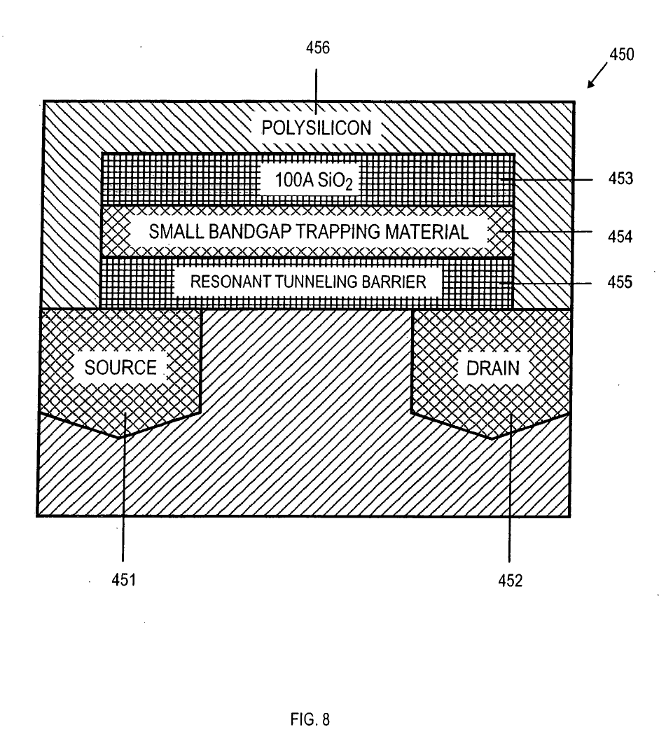

FIG. 8 illustrates a NROM device 450 utilizing resonant tunneling. In the embodiment illustrated in FIG. 8, the NROM device 450 is made of polysilicon 456 and comprises a source 451, a drain 452, a top layer 453, a small bandgap trapping layer 454 and a resonant tunneling barrier layer 455. As illustrated, the resonant tunneling barrier layer 455 is coupled to the source 451 and drain 452. The small bandgap trapping layer 454 is sandwiched between the top layer 453 and the resonant tunneling barrier layer 455. In the embodiment illustrated, the top layer 453 is SiO2. However, in alternate embodiments, the top layer 453 can be any material suitable for facilitating the programming and erasing of bits.

In additional embodiments, the trapping layer can be any small bandgap trapping material suitable to facilitate resonant tunneling. For example, the small bandgap material can include, but is not limited to Ta₂O₅ or BtiO. Further, the resonant tunneling barrier can be similar to the embodiments illustrated above or can be any material and/or configuration suitable to facilitate resonant tunneling. Because of the resonant tunneling barrier, the NROM device as illustrated in FIG. 8 operates at a substantially lower voltage thereby reducing severe short channel effects.

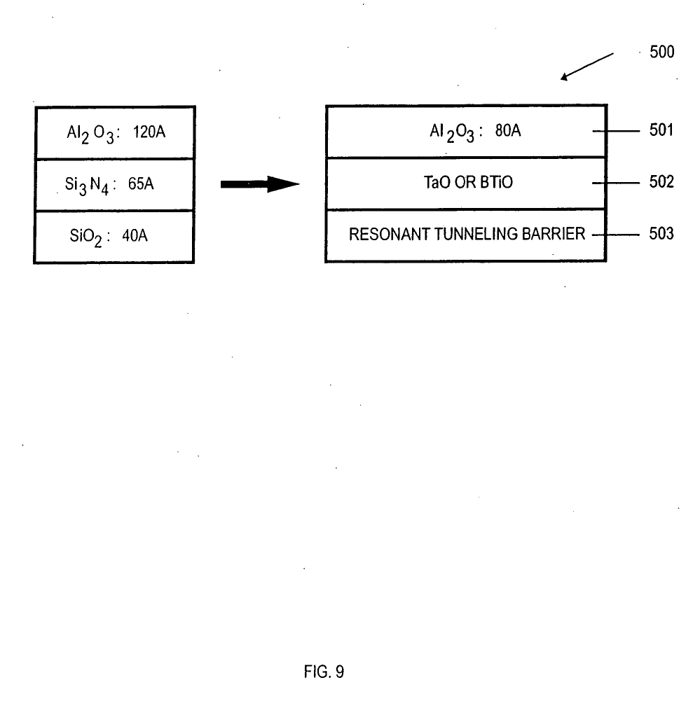

FIG. 9 illustrates a SONOS-based NAND stack 500 utilizing a resonant tunneling barrier 501. In the embodiment illustrated in FIG. 9, the SONOS-based NAND stack 500 comprises a trapping layer 502 sandwiched between a top layer 501 and a resonant tunneling barrier layer 503. As illustrated, the top layer is Al₂O₃. However, in alternate embodiments, the top layer can be any material suitable for facilitating NAND operations. Further, as illustrated, the trapping layer is TaO or BTiO. However, in alternate embodiments, the trapping layer can be any small bandgap material suitable for facilitating resonant tunneling. Moreover, the resonant tunneling barrier layer can be similar to the embodiments illustrated above or can be any material and/or configuration suitable to facilitate resonant tunneling. Because of the resonant tunneling layer, the SONOS-based NAND device illustrated in FIG. 9 operates at a substantially lower voltage thereby reducing severe short channel effects.

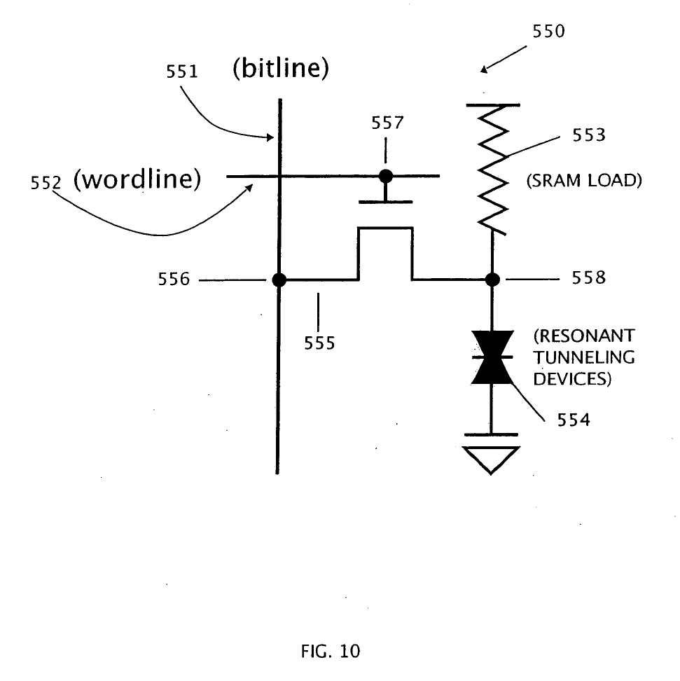

FIG. 10 illustrates a SRAM circuit 550 with a resistive load 553 and a resonant tunneling device 554. As illustrated, a word line 552 crosses a bitline 551. The wordline is coupled to a source 557 of a transistor 555 while the bitline 551 is coupled to a gate 556 of the transistor 555. A drain 558 of the transistor is coupled to a SRAM resistive load 553 and a resonant tunneling device 554. The circuit 555 has two stable states which can correspond to 0 and 1. Because of the resonant tunneling device, the illustrated circuit is a silicon-based CMOS compatible process yielding SRAM functionality.

In alternate embodiments, the components and/or configuration of the circuit can vary. For example, the transistor can be an n-type transistor, p-type transistor, switch or other component suitable for SRAM, DRAM, FPM DRAM, EDO DRAM, DDR, SDRAM, DDR SDRAM, RDRAM, RAM, ROM, PROM, EPROM, EEPROM, NVRAM, CMOS RAM, VRAM, flash or any other memory implementation. In addition, the resonant tunneling device can be a variety of different components including, but not limited to, a resonant tunneling diode. Moreover, the load can be eliminated, added or vary depending on desired and/or intended use of the circuit. Further, the configuration of the circuit can vary depending on the desired and/or intended use of the circuit including changing, adding, or eliminating the load, bitline, wordline, transistor and/or the resonant tunneling device.

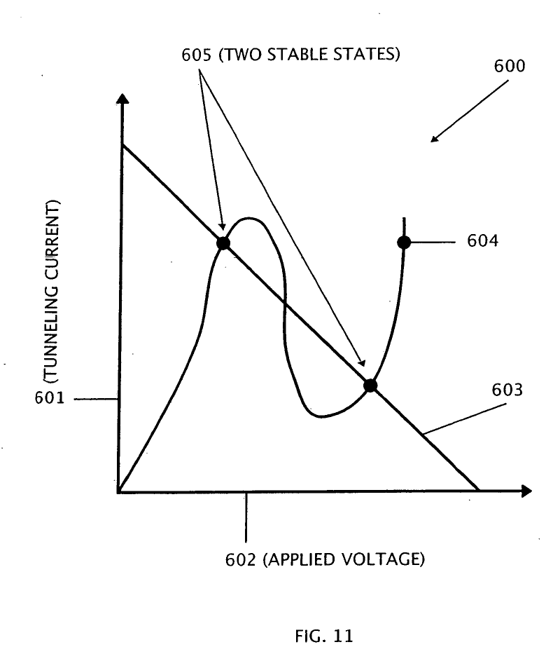

FIG. 11 illustrates a graph 600 of a resistive load 603 and a resonant tunneling device 604. As shown, a y-axis is a tunneling current 601, while an x-axis is an applied voltage 602. A plot of the tunneling current versus the applied voltage of a tunneling device 604 yields a graph similar to the embodiment illustrated in FIG. 6. A plot of the tunneling current versus the applied voltage of a resistive load 603 yields a straight line with a constant negative slope. As shown in the embodiment illustrated, the circuit has two stable states 605. Each of the stable states can represent a 0 or 1. As shown, the circuit has SRAM functionality. Further, the use of a resonant tunneling device allows the fabrication process to be silicon-based CMOS compatible.

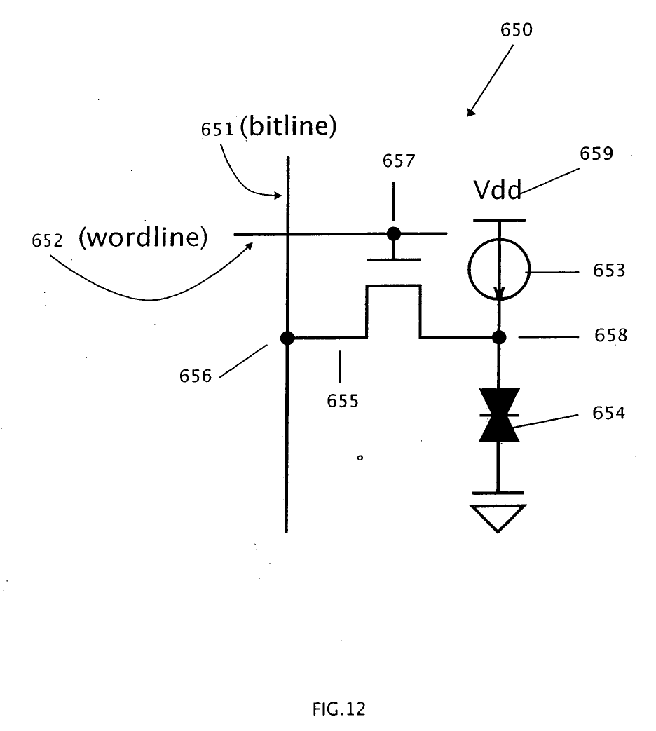

FIG. 12 illustrates a SRAM circuit 650 with a current source load 653 and a resonant tunneling device 654. As illustrated, a word line 652 crosses a bitline 651. The wordline is coupled to a source 657 of a transistor 655 while the bitline 651 is coupled to a gate 656 of the transistor 655. A drain 658 of the transistor is coupled to a current source load 653 and a resonant tunneling device 654. The current source load is additionally coupled to a voltage source 659. The circuit 655 has two stable states which can correspond to 0 and 1. Thus, the illustrated circuit is a silicon-based CMOS compatible process yielding SRAM functionality.

In alternate embodiments, the components and/or configuration of the circuit can vary. For example, the transistor can be an n-type transistor, p-type transistor, switch or other component suitable for SRAM, DRAM, FPM DRAM, EDO DRAM, DDR, SDRAM, DDR SDRAM, RDRAM, RAM, ROM, PROM, EPROM, EEPROM, NVRAM, CMOS RAM, VRAM, flash or any other memory implementation. In addition, the resonant tunneling device can be a variety of different components including, but not limited to, a resonant tunneling diode. Moreover, the load and/or voltage source can be eliminated, added or vary depending on desired and/or intended use of the circuit. Further, the configuration of the circuit can vary depending on the desired and/or intended use of the circuit including changing, adding, or eliminating the load, bitline, wordline, transistor and/or the resonant tunneling device.

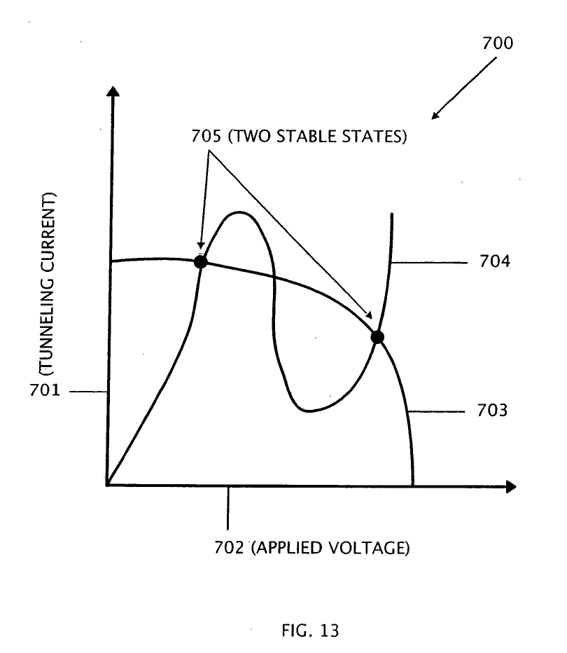

FIG. 13 illustrates a graph 700 of a current source load 703 and a resonant tunneling device 704. As shown, a y-axis is a tunneling current 701 while an x-axis is an applied voltage 702. A plot of the tunneling current versus an applied voltage of a tunneling device 704 yields a graph similar to the embodiment illustrated in FIG. 6. A plot of the tunneling current versus the applied voltage of a current source load 703 yields a curved line with a negative slope. As shown in the embodiment illustrated, the circuit has two stable states 705 where the two lines intersect. Each of the stable states can represent a 0 or 1. As shown, the circuit has SRAM functionality. Further, the use of a resonant tunneling device allows the fabrication process to be silicon-based CMOS compatible.

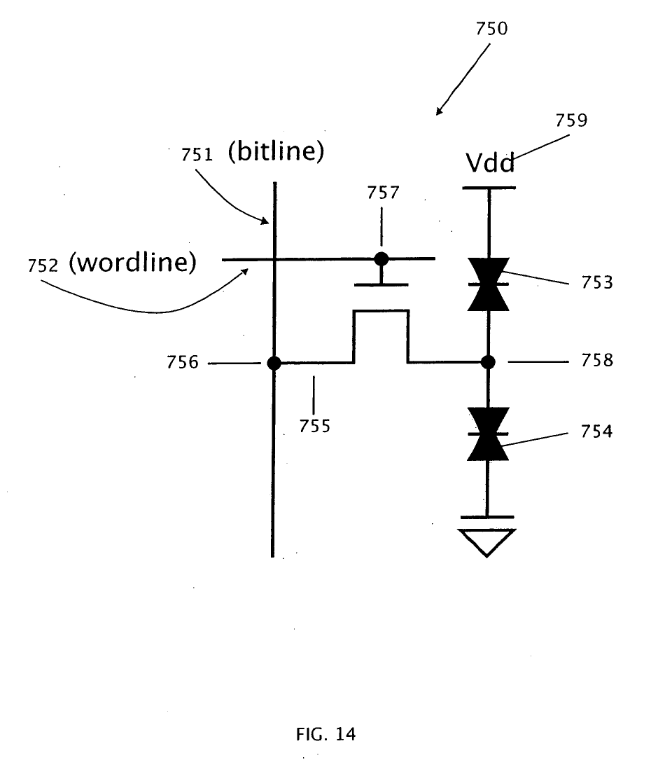

FIG. 14 illustrates a SRAM circuit 750 with a resonant tunneling device load 753 and a resonant tunneling device 754. As illustrated, a word line 752 crosses a bitline 751. The wordline is coupled to a source 757 of a transistor 755 while the bitline 751 is coupled to a gate 756 of the transistor 755. A drain 758 of the transistor is coupled to the resonant tunneling device load 753 and the resonant tunneling device 754. The resonant tunneling device load 753 is further coupled to a voltage source 759. The circuit 755 has two stable states which can correspond to 0 and 1. Thus, the illustrated circuit is a silicon-based CMOS compatible process yielding SRAM functionality.

In alternate embodiments, the components and/or configuration of the circuit can vary. For example, the transistor can be an n-type transistor, p-type transistor, switch or other component suitable for SRAM, DRAM, FPM DRAM, EDO DRAM, DDR, SDRAM, DDR SDRAM, RDRAM, RAM, ROM, PROM, EPROM, EEPROM, NVRAM, CMOS RAM, VRAM, flash or any other memory implementation. In addition, the resonant tunneling device can be a variety of different components including, but not limited to, a resonant tunneling diode. Moreover, the load and/or voltage source can be eliminated, added or vary depending on desired and/or intended use of the circuit. Further, the configuration of the circuit can vary depending on the desired and/or intended use of the circuit including changing, adding, or eliminating the load, bitline, wordline, transistor and/or the resonant tunneling device.

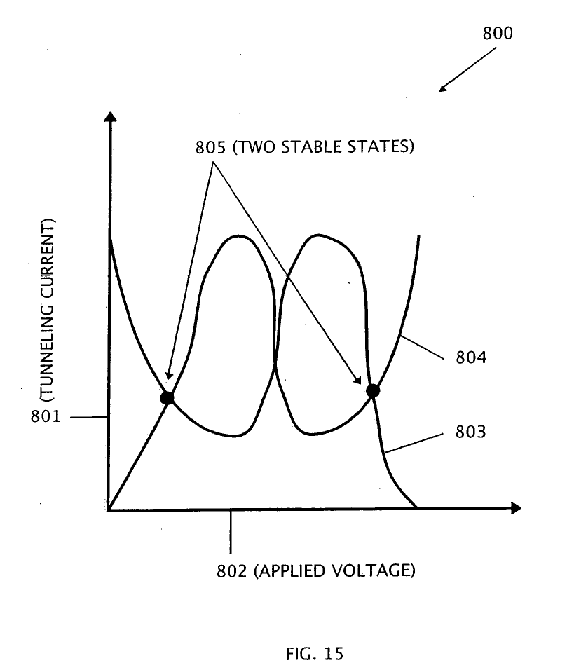

FIG. 15 illustrates a graph 800 of a resonant tunneling load 803 and a resonant tunneling device 804. As shown, a y-axis is a tunneling current 801 while an x-axis is an applied voltage 802. A plot of the resonant tunneling device 804 yields a graph similar to the embodiment illustrated in FIG. 6. A plot of the resonant tunneling load 803 yields a graph similar to the embodiment illustrated in FIG. 6 but inverted. As shown in the embodiment illustrated, the circuit has two stable states 805 where the two lines intersect. Each of the stable states can represent a 0 or 1. As shown, the circuit has SRAM functionality. Further, the use of resonant tunneling devices allows the fabrication process to be silicon-based CMOS compatible.

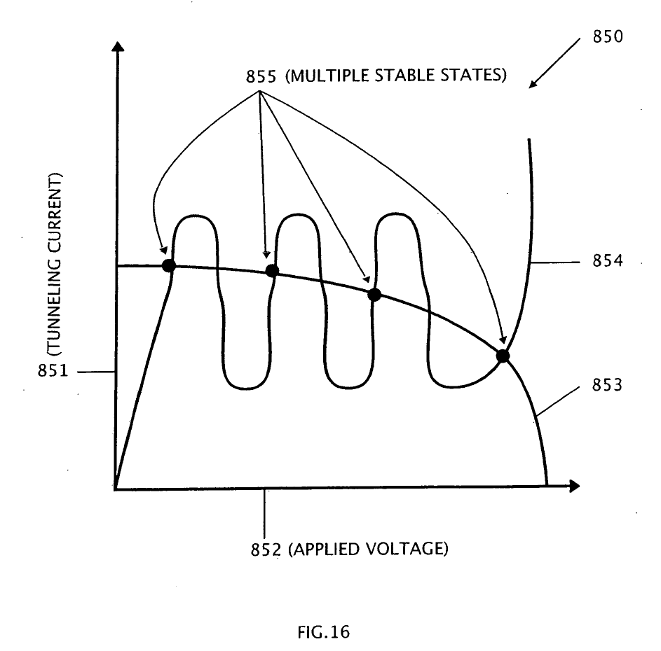

FIG. 16 illustrates a graph 850 of a current source load 853 and a resonant tunneling device 854 having two or more bits per cell. As shown, a y-axis is a tunneling current 851 while an x-axis is an applied voltage 852. A plot of the tunneling current versus the applied voltage of the resonant tunneling device 854 yields a graph having a multitude of maxima. A plot of the tunneling current versus the applied voltage of a current source load 853 yields a curved line with a negative slope. As shown in the embodiment illustrated, the circuit has four stable states 855 where the two lines intersect. Each of the stable states can represent a 0 or 1. As shown, the circuit has SRAM functionality. Further, the use of a resonant tunneling device allows the fabrication process to be silicon-based CMOS compatible. Moreover, the multi-state resonant tunneling device allows for multi-bit SRAM realization resulting in a higher density of storage bits.

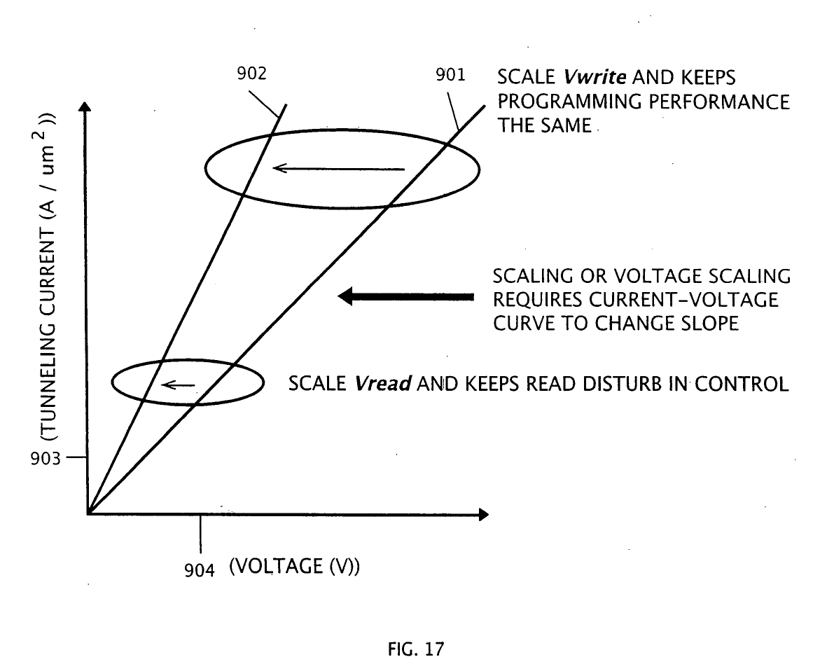

FIG. 17 illustrates a graph 900 comparing an oxide as a tunneling layer 901 to a resonant tunneling barrier as a tunneling layer 902. As shown, a y-axis is a tunneling current 903 while an x-axis is an applied voltage 904. A plot of the tunneling current versus the applied voltage of the oxide as the tunneling layer 901 yields a graph having a straight line with a small slope. A plot of the tunneling current versus the applied voltage of the resonant tunneling barrier as the tunneling layer 902 yields a straight line having a greater slope. As shown, voltage scaling is realized by replacing an oxide as a tunneling layer with a resonant tunneling barrier.

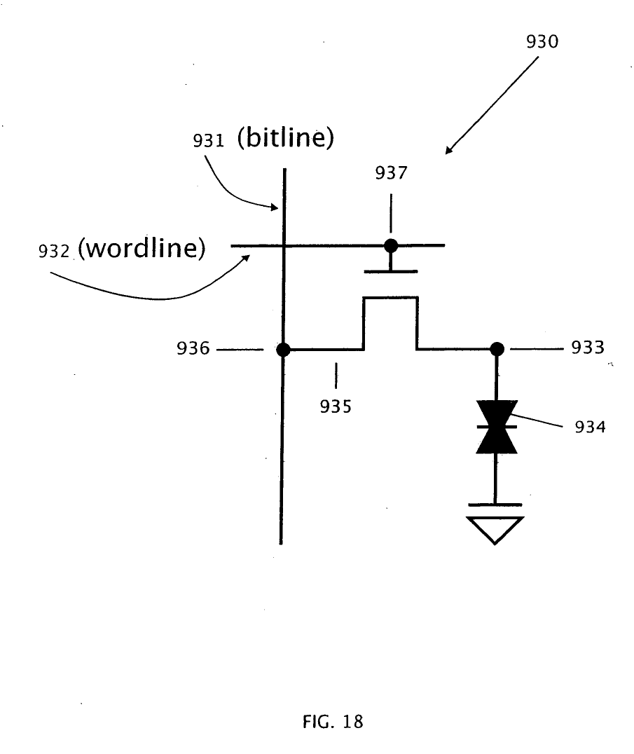

FIG. 18 illustrates a SRAM circuit 930 with no load. As illustrated, a word line 932 crosses a bitline 931. The wordline is coupled to a source 937 of a transistor 935 while the bitline 931 is coupled to a gate 936 of the transistor 935. A drain 933 of the transistor is coupled to a resonant tunneling device 934. As shown, the SRAM circuit is not coupled to a load. However, the transistor can act as a current source. Thus, the illustrated circuit is a silicon-based CMOS compatible process yielding SRAM functionality.

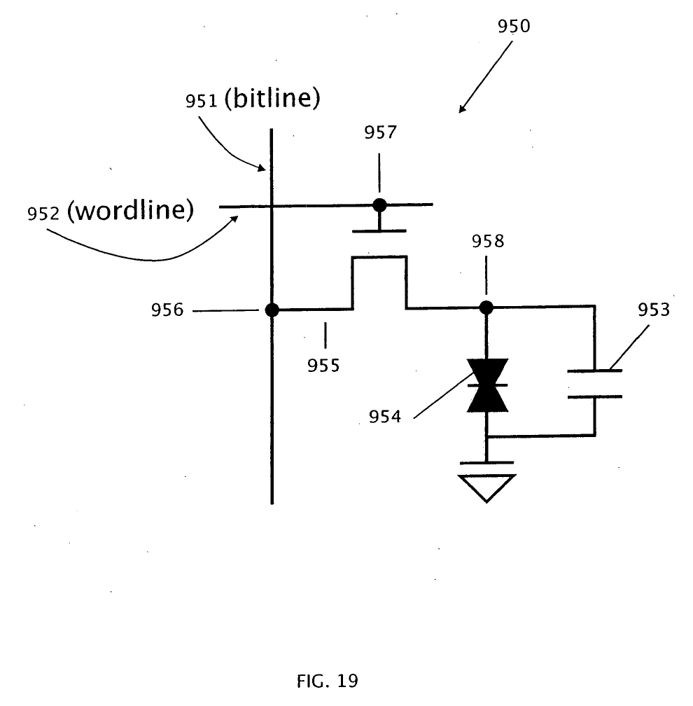

FIG. 19 illustrates a SRAM circuit 950 with a capacitor 953. As illustrated, a word line 952 crosses a bitline 951. The wordline is coupled to a source 957 of a transistor 955 while the bitline 951 is coupled to a gate 956 of the transistor 955. A drain 958 of the transistor is coupled to the capacitor 953 and a resonant tunneling device 954. The capacitor 953 and the resonant tunneling device 954 are coupled in parallel. The illustrated circuit is a silicon-based CMOS compatible process yielding SRAM functionality.

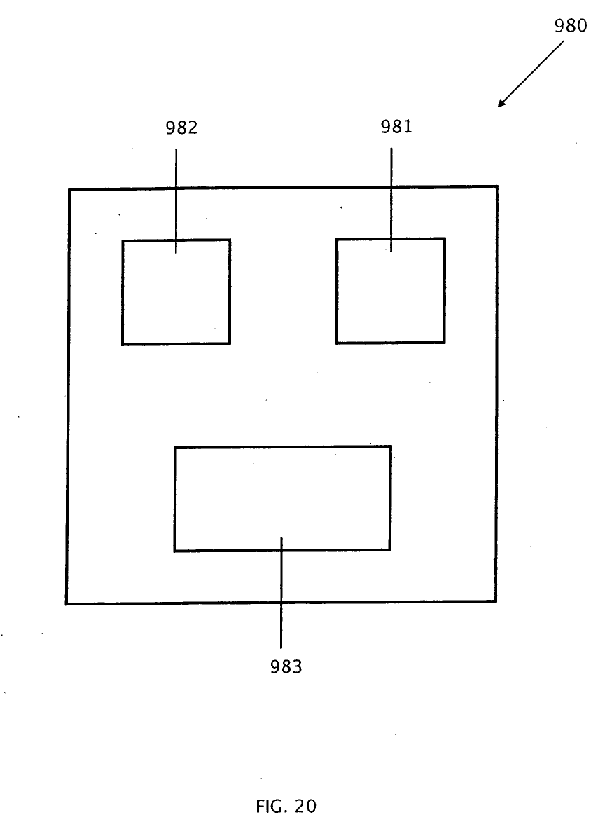

FIG. 20 illustrates an integrated circuit 980. The integrated circuit 980 comprises a SRAM device 981 as described above and a SONOS-based NAND device 983 as described above. Further, the integrated circuit includes desired circuitry 982. As shown in the embodiment illustrated, an integrated circuit with resonant tunneling devices is smaller and utilizes less voltage.

In addition to the above mentioned examples, various other modifications and alterations of the invention may be made without departing from the invention. Accordingly, the above disclosure is not to be considered as limiting and the appended claims are to be interpreted as encompassing the true spirit and the entire scope of the invention.

What is claimed is:

1. A SRAM circuit comprising:
a transistor having a source, gate and drain,
a bitline coupled to said source,
a wordline coupled to said gate, and
a resonant tunneling device coupled to said drain and a load.

2. A SONOS-based NAND device comprising:
a top layer,
a resonant tunneling barrier layer, and
a small bandgap trapping layer sandwiched between said top layer and said resonant tunneling barrier layer.

3. An integrated circuit comprising:
an SRAM circuit as claimed in claim 1, and
a SONOS-based NAND device as claimed in claim 2.
